(19) United States
(12) Patent Application Publication
(10) Pub. No.: US 2026/0354230 A1
(43) Pub. Date: Nov. 5, 2026

(54) SEMICONDUCTOR STRUCTURE AND METHOD OF FORMING

(71) Applicant: Taiwan Semiconductor Manufacturing co., Ltd., Hsinchu (TW)

(72) Inventors: Chia-Tsun Chen, Hsinchu (TW); Ting Hao Kuo, Hsinchu (TW); Yu-Chih Huang, Hsinchu (TW); Chen-Shien Chen, Zhubei (TW); Chieh-Jui Chang, Taichung (TW)

(21) Appl. No.: 19/737,814

(22) Filed: Jul. 10, 2026

Related U.S. Application Data
(63) Continuation of application No. 18/926,819, filed on Oct. 25, 2024.
(60) Provisional application No. 63/672,752, filed on Jul. 18, 2024.

(51) Int. Cl. H10W 70/65; H10W 20/00; H10W 70/63; H10W 72/90; H10W 90/00

(52) U.S. Cl. CPC H10W 70/65; H10W 20/077; H10W 70/635; H10W 72/936; H10W 72/9445; H10W 90/00; H10W 90/701; H10W 90/722; H10W 90/792; H10W 90/794

(57) ABSTRACT

A semiconductor structure includes an interposer that includes: a substrate; a redistribution structure (RDS) on the substrate; a passivation film on the RDS, where the passivation film includes a first etch stop layer (ESL) on the RDS and a first dielectric layer on the first ESL; a via embedded in the passivation film, where the via is electrically coupled to a conductive feature of the RDS; a bonding film on the passivation film, where the bonding film includes a second ESL on the passivation film and a second dielectric layer on the second ESL; and a bonding pad and a first dummy bonding pad that are embedded in the bonding film, where the bonding pad is electrically coupled to the via, and the first dummy bonding pad is electrically isolated; and a die attached to the interposer, where a die connector of the die is bonded to the bonding pad.

### PRIORITY CLAIM AND CROSS-REFERENCE

This application is a continuation of U.S. patent application Ser. No. 18/926,819, filed Oct. 25, 2024 and entitled “Semiconductor Structure and Method of Forming,” which claims priority to U.S. Application No. 63/672,752, filed Jul. 18, 2024 and entitled “A Film Scheme for Bottom Wafer (Interposer) PASS-Layer in SoIC,” which applications are hereby incorporated herein by reference.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

As the demand for shrinking electronic devices has grown, a need for smaller and more creative packaging techniques of semiconductor dies has emerged. An example of such packaging systems is Package-on-Package (PoP) technology. In a PoP device, a top semiconductor package is stacked on top of a bottom semiconductor package to provide a high level of integration and component density. Another example is a Chip-On-Wafer-On-Substrate (CoWoS) technology. In some embodiments, to form a CoWoS structure, a plurality of semiconductor chips are attached to a wafer, and a dicing process is performed next to separate the wafer into a plurality of interposers, where each of the interposers has one or more semiconductor chips attached thereto. The interposer with semiconductor chips(s) attached is referred to as a Chip-On-Wafer (CoW) structure. The CoW structure is then attached to a substrate (e.g., a printed circuit board) to form a CoWoS structure. Yet another example is the System on Integrated Chips (SoIC) technology, which is a three-dimensional (3D) inter-chip stacking technology that integrates active and passive chips into a single SoC system. The SoIC platform uses front-end technologies and precision methodologies from silicon fabs to stack chips in 3D. The SoIC platform allows for the integration of known good dies (KGDs) with different chip sizes, functionalities, and wafer node technologies. The resulting structure enables ultra-high-density vertical stacking to achieve high performance, low power, and low resistance-inductance-capacitance (RLC). These and other advanced packaging technologies enable production of semiconductor devices with enhanced functionalities and small footprints.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1-5, 6A, 6B, 6C, 6D, and 6E illustrate various views of a semiconductor structure at various stages of manufacturing, in accordance with an embodiment.

FIGS. 7A and 7B illustrate various views of a semiconductor structure, in accordance with another embodiment.

FIG. 8 illustrates a cross-sectional view of a semiconductor structure, in accordance with yet another embodiment.

FIG. 9 illustrates a flow chart of a method of forming a semiconductor structure, in some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. Throughout the description, unless otherwise specified, the same or similar reference numerals in different figures refer to the same or similar component formed by a same or similar method using a same or similar material(s).

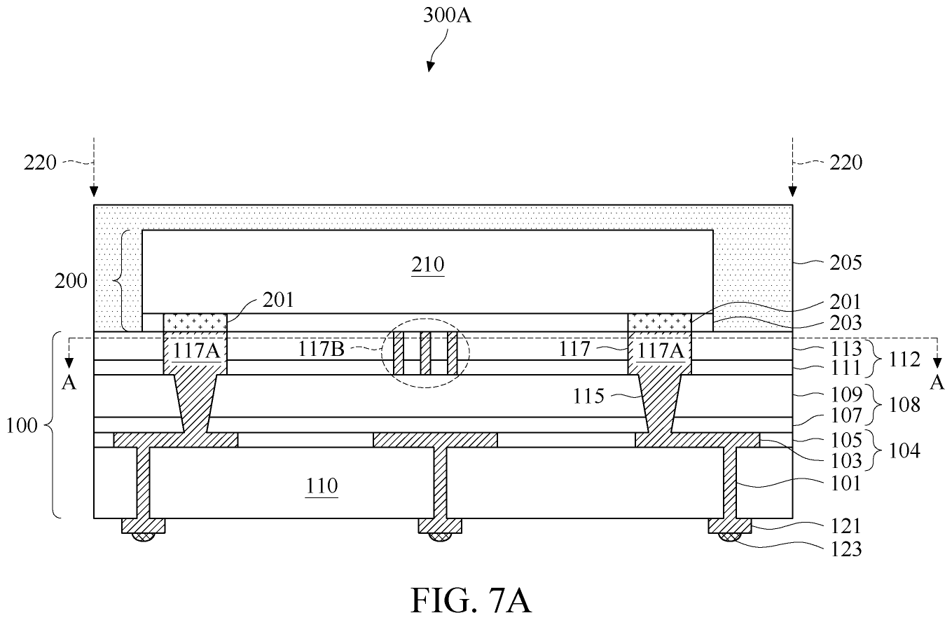

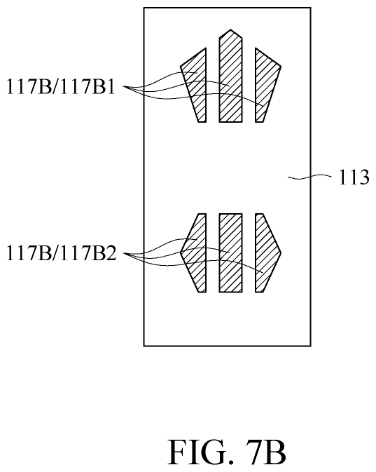

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. In the discussion herein, figures with the same numeral but different letters (e.g., FIGS. 7A and 7B) illustrate various views of the same semiconductor structure at a same manufacturing stage.

In some embodiments, the passivation film for an interposer includes only one ESL layer and one dielectric layer, which simplifies the film scheme and reduces production cost and process time. Due to the reduced thickness of the passivation film, vias formed in the passivation film have shorter lengths and larger bottom surfaces, which advantageously reduce the electrical resistance of the vias. Furthermore, since there is only one interface between the ESL and the dielectric layers within the passivation film, the risk of delamination of the passivation film from the vias is reduced.

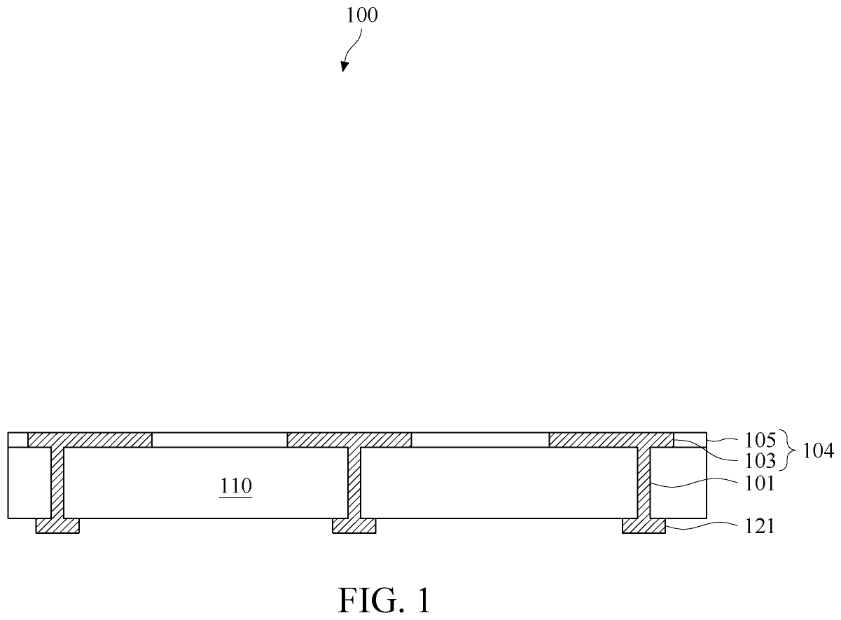

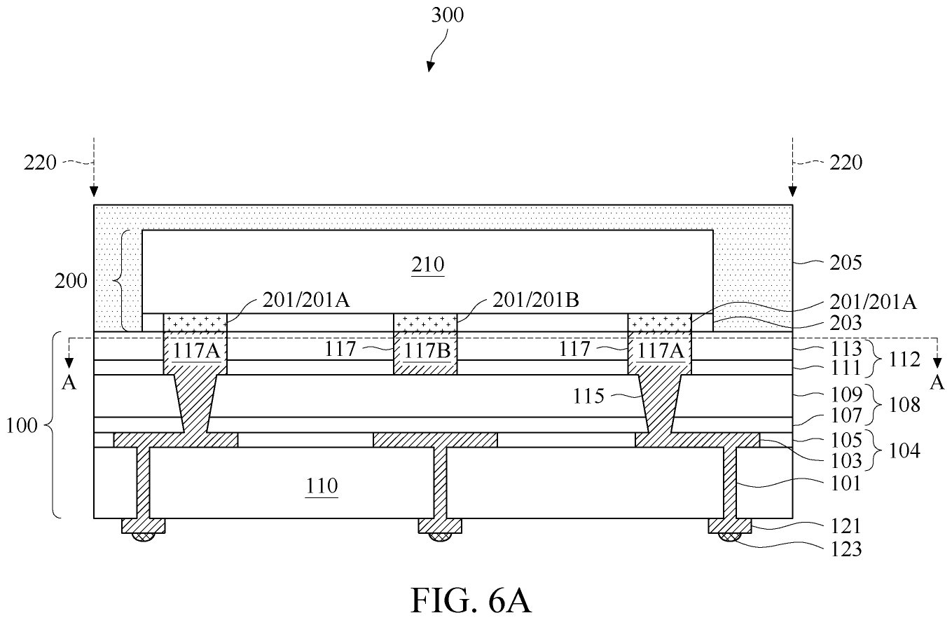

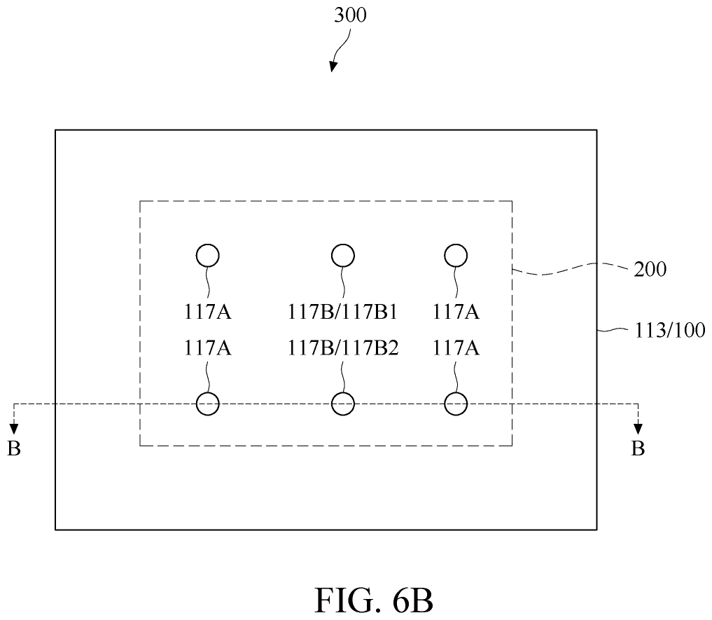

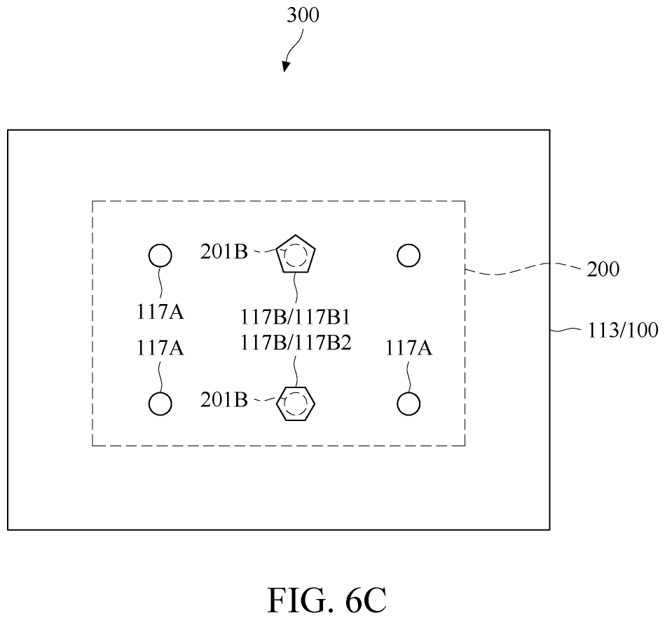

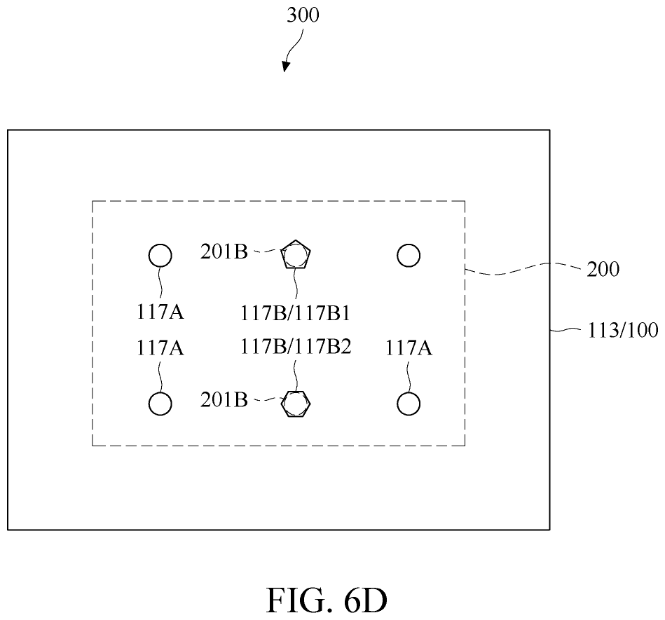

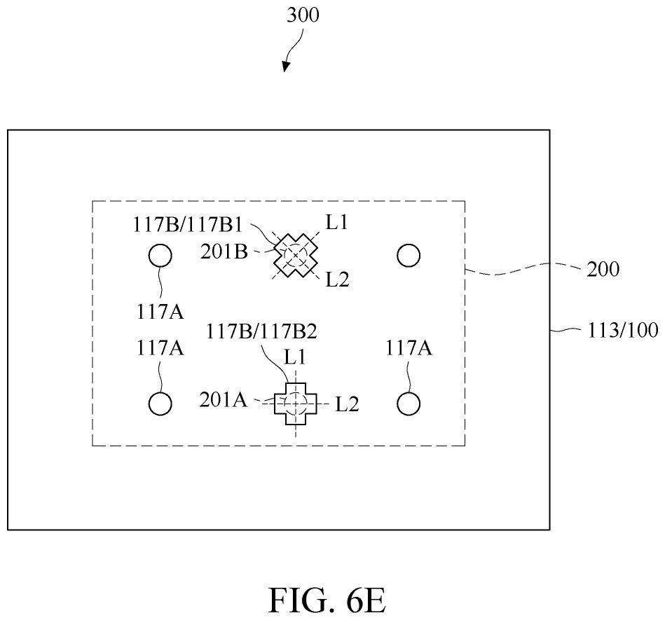

FIGS. 1-5, 6A, 6B, 6C, 6D, and 6E illustrate various views (e.g., cross-sectional view, top view) of a semiconductor structure 300 at various stages of manufacturing, in accordance with an embodiment. The semiconductor structure 300 may be, e.g., an SoIC device. In the illustrated embodiment, the semiconductor structure 300 includes an interposer 100 and a die 200 attached to the interposer 100. FIGS. 1-5 illustrate the manufacturing processing steps for forming the interposer 100. FIG. 6A-6E illustrate various views of the semiconductor structure 300 after the die 200 is attached to the interposer 100.

FIG. 1 illustrates a cross-sectional view of an interposer 100 at an early stage of manufacturing. The interposer 100 may be a portion of a wafer which is diced later to form a plurality of interposers 100 (e.g., multiple, individual interposers 100) with dies attached thereon.

The interposer 100 in FIG. 1 includes a substrate 110, through vias 101, a redistribution structure (RDS) 104 formed on an upper surface of the substrate 110, and conductive pads 121 (e.g., copper pads) formed on a lower surface of the substrate 110. A passivation layer may be formed at the lower surface of the substrate 110 to covers at least portions of the conductive pads 121. External connectors 123 (see FIG. 6A) are formed subsequently on the conductive pads 121 to provide electrical connection to other device(s).

The substrate 110 may be, e.g., a silicon substrate, doped or undoped, or an active layer of a silicon-on-insulator (SOI) substrate. However, the substrate 110 may alternatively be a glass substrate, a ceramic substrate, a polymer substrate, or any other substrate that may provide a suitable protection and/or interconnection functionality.

In some embodiments, the substrate 110 may include electrical components, such as resistors, capacitors, or the like. These electrical components may be active, passive, or a combination thereof. In other embodiments, the substrate 110 is free from both active and passive electrical components, and simply includes conductive lines and/or vias to provide electrical connection. These and other variations are fully intended to be included within the scope of this disclosure.

Through vias 101 extend from the upper surface of the substrate 110 to the lower surface of the substrate 110, and provide electrical connections between the conductive pads 121 and conductive features of the RDS 104. The through vias 101 may be formed of a suitable conductive material such as copper, tungsten, aluminum, alloys, doped polysilicon, combinations thereof, and the like. A barrier layer may be formed between the through vias 101 and the substrate 110. The barrier layer may comprise a suitable material such as titanium nitride, although other materials, such as tantalum nitride, titanium, or the like, may alternatively be utilized.

The RDS 104 is formed on the upper surface of the substrate 110. The RDS 104 may include one or more dielectric layers 105 (e.g., silicon oxide) and conductive features 103 (e.g., conductive lines, vias) formed in the one or more dielectric layers 105. In the example of FIG. 1, the RDS 104 is illustrated as having one dielectric layer 105 and conductive features 103 (e.g., conductive pads, conductive lines) formed in the dielectric layer 105, with the understanding that multiple dielectric layers 105 and multiple layers of conductive features may be formed in the RDS 104.

In some embodiments, the one or more dielectric layers 105 are formed of a nitride such as silicon nitride; an oxide such as silicon oxide, phosphosilicate glass (PSG), borosilicate glass (BSG), boron-doped phosphosilicate glass (BPSG), or the like; or the like. The one or more dielectric layers 105 may be formed by any acceptable deposition process, such as spin coating, chemical vapor deposition (CVD), laminating, the like, or a combination thereof.

In some embodiments, the conductive features 103 of the RDS 104 comprise conductive lines and/or via formed of a suitable conductive material such as copper, titanium, tungsten, aluminum, or the like. In some embodiments, the conductive features 103 is formed of an alloy, such as an aluminum-copper alloy, a titanium-aluminum-copper alloy, or the like. The RDS 104 may be formed by, e.g., forming a dielectric layer 105, forming openings in the dielectric layer 105 to expose underlying conductive features, forming a seed layer over the dielectric layer 105 and in the openings, forming a patterned photoresist with a designed pattern over the seed layer, plating (e.g., electroplating or electroless plating) the conductive material in the designed pattern and over the seed layer, and removing the photoresist and portions of seed layer on which the conductive material is not formed. The above described processing may be repeated until a target number of layers of dielectric layers 105 and conductive features 103 are formed.

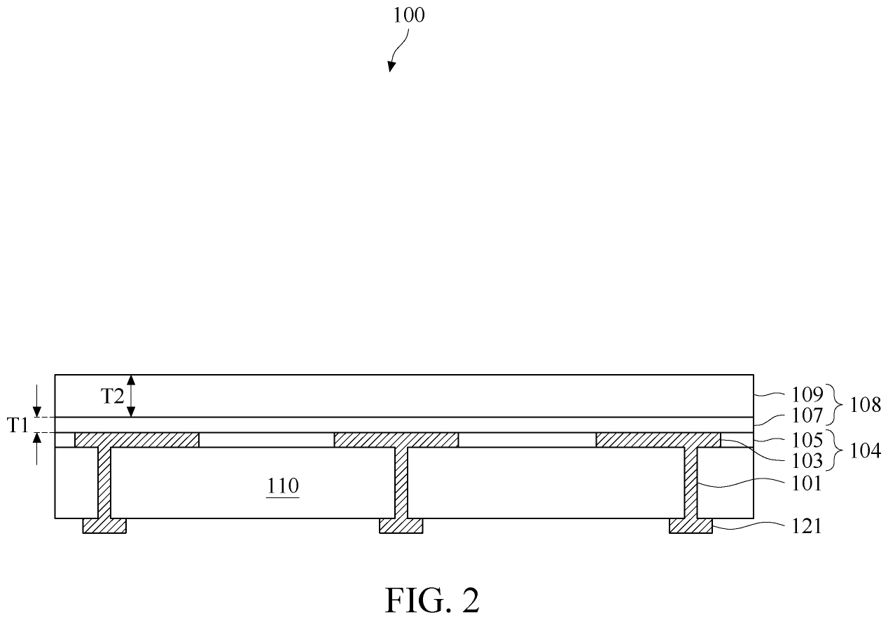

Next, in FIG. 2, a passivation film 108 (may also be referred to as a passivation structure) is formed on the RDS 104. In the illustrated embodiment, the passivation film 108 includes an etch stop layer (ESL) 107 and a dielectric layer 109 on the ESL 107.

In some embodiments, the ESL 107 is formed of a suitable material such as silicon nitride (e.g., SiN), silicon carbide (e.g., SiC), silicon carbonitride (e.g., SiCN), silicon oxynitride (SiON), or the like, and may be formed by a suitable formation method, such as physical vapor deposition (PVD), chemical vapor deposition (CVD), plasma-enhanced CVD (PECVD), or the like. The ESL 107 is used to protect the underlying structures and provide a control point for a subsequent etching process, in some embodiments. A thickness T₁ of the ESL 107 may be between about 300 angstroms and about 5000 angstroms, such as between 1000 angstroms and 5000 angstroms, or between 3000 angstroms and about 5000 angstroms. In some embodiments, the thickness T₁ of the ESL 107 is larger than the typical thickness of the ESL in a passivation film of an interposer without the presently disclosed structure, which typical thickness may be about 700 angstroms or less. As will be discussed in more detail hereinafter, the increased thickness T₁ of the ESL 107 reliably protects the underlying conductive features (e.g., the topmost conductive features 103 of the RDS 104) from a subsequent etching process, and provides a control point for stopping the subsequent etching process.

The dielectric layer 109 is formed on the ESL 107 using a suitable material such as silicon oxide (e.g., SiO), although other suitable materials may also be used. A suitable formation method, such as PVD, CVD, PECVD, may be performed to form the dielectric layer 109. In the illustrated embodiments, the thickness T₁ of the ESL 107 is no less than one seventh of a thickness T₂ of the dielectric layer 109, and is no greater than the thickness T₂ (e.g., T₂/7≤T₁≤T₂). For example, the thickness T₁ may be between about 12.5% and about 50% of a thickness T (e.g., T=T₁+T₂) of the passivation film 108. The thickness T of the passivation film 108 may be between about 0.1 μm and about 3 μm, as an example. The lower boundary (e.g., 0.1 μm) of the thickness T ensures sufficient electrical isolation between the subsequently formed dummy bonding pads 117B and the underlying conductive features 103, and the upper boundary (e.g., 3 μm) of the thickness T ensures small electrical resistance for the subsequently formed vias 115. More details are discussed hereinafter.

The disclosed range (e.g., T₂/7≤T₁≤T₂) for the thickness T₁ ensures that the passivation film 108 functions as designed and provides enough protection for the underlying structures (e.g., the conductive features 103). Note that in the illustrated embodiments, the passivation film 108 only include a single layer of ESL 107 and a single layer of dielectric layer 109, whereas a typical passivation film for an interposer may include multiple ESLs and multiple dielectric layers interleaved with each other. In some embodiments, in a subsequent etching process to form via openings (for forming vias 115), the ESL 107 (e.g., a carbon-containing or nitride-containing material) is used to control the stopping point of the etching process. For example, an optical emission spectrometer (OES) may be used to detect the carbon or nitrogen elements when the etching process reaches the ESL 107 and to signal that the etching process should be ended soon, and in response, the etching process may be controlled/adjusted accordingly to stop at the right time. If the thickness T₁ is too smaller (e.g., smaller than T₂/7), the ESL 107 may already be etched through before the OES reliably detects the carbon or nitrogen elements, thus not providing enough buffer time for stopping the etching process and not providing enough protection for the underlying structures. Conversely, if the thickness T₁ is too large (e.g., larger than T₂), it may take too long to etch through the ESL 107, thus increasing the processing time and cost.

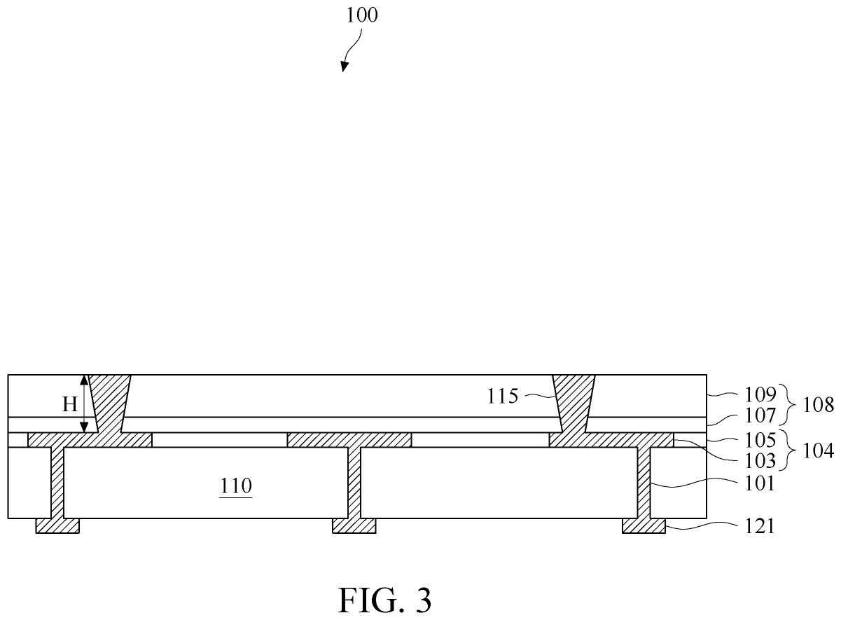

Next, in FIG. 3, vias 115 are formed in the passivation film 108. In some embodiments, the vias 115 are formed of a suitable conductive material, such as copper, an aluminum-copper alloy, a titanium-aluminum-copper alloy, or the like. To form the vias 115, via openings are formed to extend through the passivation film 108 to expose the underlying conductive features 103 (e.g., a topmost conductive pattern of the RDS 104), the conductive material is then formed in the via openings, and a planarization process, such as chemical-mechanical planarization (CMP), is performed next to remove excess portions of the conductive material from the upper surface of the passivation film 108 and to achieve a coplanar upper surface between the passivation film 108 and the remaining portions of the conductive material. The remaining portions of the conductive material in the via openings form the vias 115.

The vias openings may be formed by an etching process that includes two etching steps. For example, a first plasma etching process may be performed as a first etching step using a first gas source to etch through the dielectric layer 109 and to expose the ESL 107. Next, a second plasma etching process may be performed as a second etching step using a second gas source to etch through the ESL 107. The first gas source may comprise, e.g., C₄F₆, to selectively etch the dielectric layer 109. The second gas source may comprise, e.g., CF₄, CHF₃, and O₂ to selectively etch the ESL 107. As discussed above, an OES may be used to detect the carbon or nitrogen elements when the etching process reaches the ESL 107, and to control/adjust the etching process accordingly to stop at the right time to avoid damaging the underlying conductive features 103.

Advantages are achieved by the structure of the disposed passivation film 108. For example, the passivation film 108 includes only one ESL 107 and one dielectric layer 109, and therefore, has only one interface between the ESL 107 and the dielectric layer 109. As a result, the vias 115 only extend through one interface (e.g., between the ESL 107 and the dielectric layer 109) within the passivation film 108. In some embodiments, the more interfaces of the passivation film 108 the vias 115 have to extend through, the higher the risk of delamination for the passivation film 108. Since the disclosed passivation film 108 has only one interface, the risk of delamination for the passivation film 108 is reduced significantly. In addition, since the passivation film 108 has few layers, its thickness T is reduced. Accordingly, the height H of the via 115 is reduced. In some embodiments, the height H of the via 115 is between about 0.1 μm and about 3 μm, which may be smaller than that of vias formed in passivation films with multiple ESLs and multiple dielectric layers by 75% or more. Since the vias 115 typically have tapered sidewalls (due to characteristics of etching process for forming the via openings), a shorter via 115 has a larger bottom surface area for contacting the underlying conductive feature 103. The larger bottom surface area and the shorter height of the via 115 advantageously reduce the electrical resistance of the via 115.

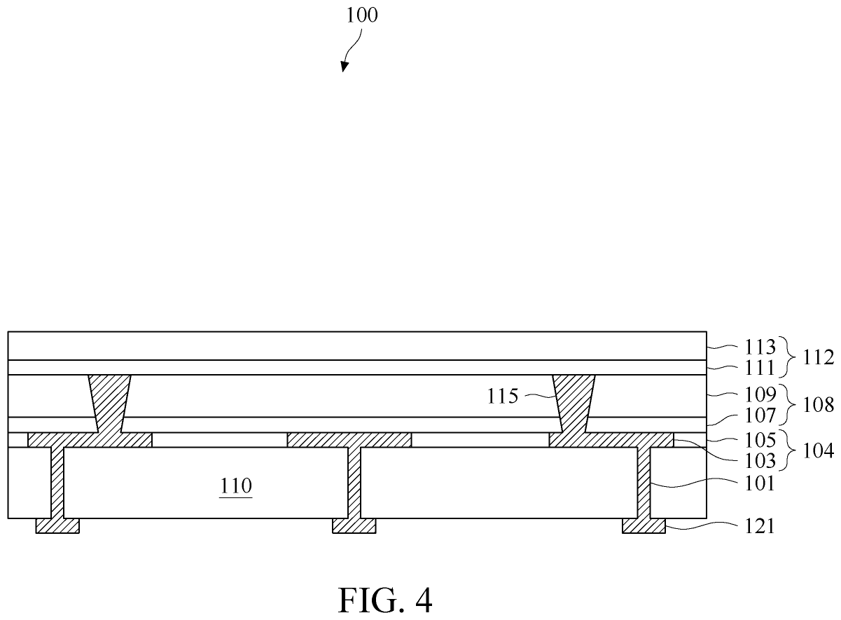

Next, in FIG. 4, a bonding film 112 is formed on the passivation film 108. In the illustrated embodiment, the bonding film 112 includes an ESL 111 and a dielectric layer 113. The ESL 111 and the dielectric layer 113 may be the same as or similar to the ESL 107 and the dielectric layer 109 of the passivation film 108, respectively, and may be formed by the same formation method using the same materials(s), thus details are not repeated.

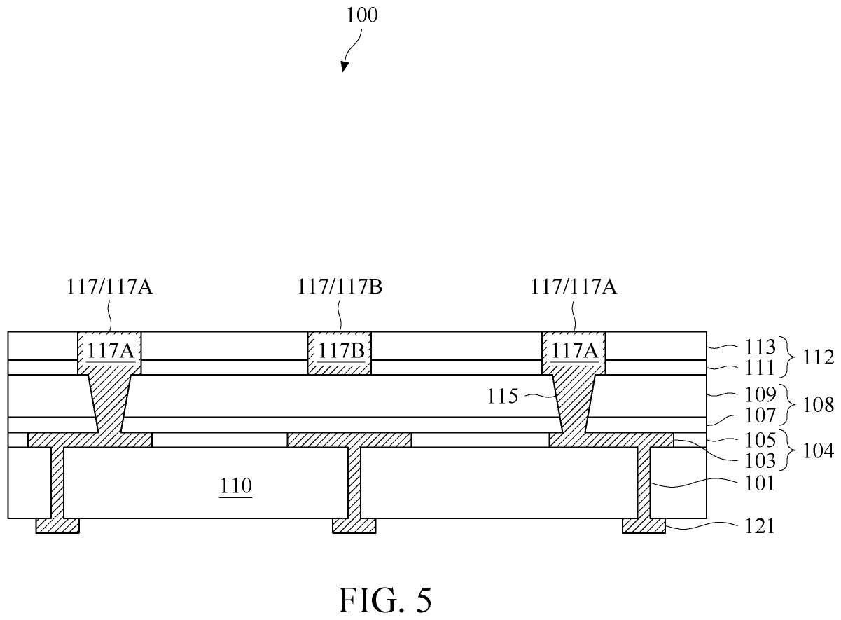

Next, in FIG. 5, bonding pads 117 (e.g., 117A and 117B) are formed in the bonding film 112. In some embodiments, the bonding pads 117 are formed of a suitable conductive material, such as copper, an aluminum-copper alloy, a titanium-aluminum-copper alloy, or the like. To form the bonding pads 117A, pad openings are formed to extend through the bonding film 112 to expose the underlying vias 115, the conductive material is then formed in the pad openings, and a planarization process, such as CMP, is performed next to remove excess portions of the conductive material from the upper surface of the bonding film 112 and to achieve a coplanar upper surface between the bonding film 112 and the remaining portions of the conductive material. The remaining portions of the conductive material in the pad openings form the bonding pads 117A.

Notably in FIG. 5, dummy bonding pads 117B are also formed in the bonding film 112. The dummy bonding pads 117B are electrically isolated, in the illustrated embodiments. In some embodiments, the dummy bonding pads 117B are formed in the bonding film 112 to achieve a substantially uniform metal density in the bonding film 112, in order to avoid or reduce surface unevenness (e.g., dishing) for the bonding film 112 during the planarization process (e.g., CMP). The dummy bonding pads 117B may be formed at the same time with the bonding pads 117A using the same processing steps, except that the dummy bonding pads 117B are electrically isolated (e.g., not electrically coupled to the vias 115). The dummy bonding pads 117B may or may not have the same shape as the bonding pads 117A, details are discussed hereinafter.

After the bonding pads 117 are formed, the structure in FIG. 5 illustrates an interposer 100 of the present disclosure. The interposer 100 is used to form the semiconductor structure 300 of FIG. 6A.

Next, in FIG. 6A, a die 200 is attached (e.g., bonded) to the interposer 100. Next, a molding material 205 is formed on the interposer 100 around the die 200. In some embodiments, multiple semiconductor structures 300 are formed on a same wafer, and a dicing process may be performed next along dicing regions indicated by the dashed lines 220 to form individual (e.g., separate) semiconductor structures 300.

FIG. 6A illustrates one die 200 in the semiconductor structure 300 as a non-limiting example, with the understanding that any suitable number of dies may be attached to the interposer 100. For example, multiple dies may be disposed laterally and/or vertically with respect to each other to form 3D stacked dies in the semiconductor structure 300.

In some embodiments, the die 200 includes a substrate 210, electrical components (e.g., transistors, resistors, capacitors, diodes, or the like) formed in/on the substrate 210, and an interconnect structure over the substrate 210 connecting the electrical components to form functional circuits of the die 200. The die 200 also includes conductive pillars 201A (also referred to as die connectors 201A) that provide electrical connection to the circuits of the die 200. In addition, the die 200 may include dummy conductive pillars 201B (also referred to as dummy die connectors 201B) for bonding with the dummy bonding pads 117B of the interposer 100. The dummy conductive pillars 201B are electrically isolated, in some embodiments. The conductive pillars 201A and the dummy conductive pillars 201B may be collectively referred to as conductive pillars 201 (or die connectors 201).

The substrate 210 of the die 200 may be a semiconductor substrate, doped or undoped, or an active layer of a silicon-on-insulator (SOI) substrate. Generally, an SOI substrate comprises a layer of a semiconductor material such as silicon, germanium, silicon germanium, SOI, silicon germanium on insulator (SGOI), or combinations thereof. Other substrates that may be used include multi-layered substrates, gradient substrates, or hybrid orientation substrates.

The electrical components of the die 200 comprise a wide variety of active devices (e.g., transistors) and/or passive devices (e.g., capacitors, resistors, inductors), and the like. The electrical components of the die 200 may be formed using any suitable methods either within or on the substrate 210 of the die 200. The interconnect structure of the die 200 comprises one or more metallization layers (e.g., copper layers) formed in one or more dielectric layers, and is used to connect the various electrical components to form functional circuitry.

One or more passivation layers may be formed over the interconnect structure of the die 200 in order to provide a degree of protection for the structures of the die 200. The passivation layer may be made of one or more suitable dielectric materials such as silicon oxide, silicon nitride, low-k dielectrics such as carbon doped oxides, extremely low-k dielectrics such as porous carbon doped silicon dioxide, combinations of these, or the like. The passivation layer may be formed through a process such as chemical vapor deposition (CVD), although any suitable process may be utilized.

Conductive pads (not shown) may be formed over the passivation layer and may extend through the passivation layer to be in electrical contact with the interconnect structure of the die 200. The conductive pads may comprise aluminum, but other materials, such as copper, may alternatively be used.

Die connectors 201 of the die 200 are formed on the conductive pads to provide conductive regions for electrical connection to the circuits of the die 200. The die connectors 201 may be copper pillars, contact bumps such as microbumps, or the like, and may comprise a material such as copper, tin, silver, or other suitable material. A dielectric layer 203, such as an oxide layer (e.g., SiO), may be formed around the die connectors 201.

In some embodiments, the die connectors 201 of the die 200 are bonded to respective bonding pads 117 of the interposer 100 by a direct bonding process without using an adhesive material (e.g., a solder material), e.g., by direct metal-to-metal bonding and direct dielectric-to-dielectric bonding. The direct bonding process may include cleaning the surfaces of the die 200 and the interposer 100, aligning the die connectors 201 with respective bonding pads 117, and pressing the die connectors 201 and the bonding pads 117 together. A heat treatment may be performed to facilitate the direct bonding process. The resulting bonds between the die 200 and the interposer 100 include both dielectric-to-dielectric bonds (e.g., dielectric layers 203 to dielectric layer 113) and metal-to-metal bonds (e.g., die connectors 201 to bonding pads 117).

Next, the molding material 205 is formed on the interposer 100 around the die 200. The molding material 205 may comprise an epoxy, an organic polymer, a polymer with or without a silica-based filler or glass filler added, or other materials, as examples. In some embodiments, the molding material 205 comprises a liquid molding compound (LMC) that is a gel type liquid when applied. The molding material 205 may also comprise a liquid or solid when applied. Alternatively, the molding material 205 may comprise other insulating and/or encapsulating materials. The molding material 205 is applied using a wafer level molding process in some embodiments. The molding material 205 may be molded using, for example, compressive molding, transfer molding, molded underfill (MUF), or other methods.

Next, the molding material 205 is cured using a curing process, in some embodiments. The curing process may comprise heating the molding material 205 to a predetermined temperature for a predetermined period of time, using an anneal process or other heating process. The curing process may also comprise an ultra-violet (UV) light exposure process, an infrared (IR) energy exposure process, combinations thereof, or a combination thereof with a heating process. Alternatively, the molding material 205 may be cured using other methods. In some embodiments, a curing process is not included.

After the molding material 205 is formed, a planarization process, such as CMP, may be performed to achieve a planar upper surface for the molding material 205. In the illustrated embodiments, the molding material 205 extends further from the interposer 100 than the die 200, thus covering the upper surface of the die 200. Sidewalls of the molding material 205 are aligned with respective sidewalls of the interposer 100 along the same vertical lines, e.g., due to dicing.

As illustrated in FIG. 6A, external connectors 123 (may also be referred to as conductive bumps) are formed on the conductive pads 121. The external connectors 123 may be any suitable type of external contacts, such as microbumps, copper pillars, a copper layer, a nickel layer, a lead free (LF) layer, an electroless nickel electroless palladium immersion gold (ENEPIG) layer, a Cu/LF layer, a Sn/Ag layer, a Sn/Pb, combinations of these, or the like. The external connectors 123 may be formed on the conductive pads 121 before the dicing process. For example, after the molding material 205 is formed, the wafer comprising the semiconductor structures 300 is flipped upside down, and the side of the wafer with the molding material 205 is attached to a dicing tape. Next, the external connectors 123 are formed on the conductive pads 121 using a suitable formation method. The dicing process is performed next to separate the wafer into individual semiconductor structures 300.

FIG. 6B illustrates an example cross-sectional view of the semiconductor structure 300 along cross-section A-A in FIG. 6A. FIG. 6A corresponds to the cross-sectional view along cross-section B-B in FIG. 6B.

FIG. 6B shows the sidewalls of the dielectric layer 113 (which overlap completely with the sidewalls of the interposer 100). The sidewalls of the die 200, which are not visible in the cross-section A-A, are illustrated in dashed line in FIG. 6B. The cross-sections of the bonding pads 117 (e.g., 117A and 117B), which have the same shapes as the top views of the bonding pads 117, are also illustrated in FIG. 6B.

In the example of FIG. 6B, the bonding pads 117A and the dummy bonding pads 117B have a same shape (e.g., a circular shape). In FIG. 6B, two rows of bonding pads 117 are shown, with each row comprising two bonding pads 117A and one dummy bonding pad 117B (e.g., labeled as 117B1 in the top row, and 117B2 in the bottom row). In some embodiments, all of the die connectors 201 (e.g., 201A and 201B) of the die 200 have the same shape (e.g., cross-section view, or top view), which shape matches that of the bonding pad 117A. Since both the bonding pads 117A and dummy bonding pads 117B have the same shape in FIG. 6B, the die connectors 201A and 201B, the bonding pads 117A, and the dummy bonding pads 117B all have the same shape in the example of FIG. 6B. Note that the number, the shapes, the sizes, and the locations of the bonding pads 117 (e.g., 117A, 117B1, 117B2) shown in FIG. 6B (and FIGS. 6C, 6D and 6E) are non-limiting examples. Other numbers, other shapes, other sizes, and other locations for the bonding pads 117 are also possible, and are fully intended to be included within the scope of the present disclosure.

FIG. 6C illustrates another example cross-sectional view of the semiconductor structure 300 along cross-section A-A in FIG. 6A. In the example of FIG. 6C, the dummy bonding pad 117B1 has a first shape (e.g., a pentagon shape), the dummy bonding pads 117B2 have a second shape (e.g., a hexagon shape), and the bonding pads 117A has a third shape (e.g., a circular shape), wherein the first shape, the second shape, and the third shape are different shapes. FIG. 6C further illustrates, in dashed lines, cross-sections of the dummy die connectors 201B coupled to the dummy bonding pads 117B (e.g., 117B1 and 117B2). As illustrated in FIG. 6C, the dummy die connectors 201B and the bonding pads 117A have the same shape (e.g., a circular shape). When aligned and bonded together, in a top view (or a plan view where the die connectors 201 and the bonding pads 117 are projected onto a same plane), each dummy die connector 201B is disposed within the boundaries (e.g., sidewalls) of the corresponding dummy bonding pad 117B (e.g., 117B1, or 117B2). In particular, in FIG. 6C, the center of each dummy die connector 201B coincides (e.g., overlaps) with the center of the corresponding dummy bonding pad 117B, and the sidewalls of each dummy die connector 201B are spaced apart from (e.g., do not contact) the sidewalls of the corresponding dummy bonding pad 117B. FIG. 6C does not illustrate the cross-sections of the die connectors 201A coupled to the bonding pads 117A, because the sidewalls of each die connector 201A overlap (e.g., overlap completely) with the sidewalls of the corresponding bonding pad 117A.

Allowing different shapes and sizes for the dummy bonding pads 117B may provide advantages. For example, the dummy bonding pads 117B with different shapes may serve as reference points for a pick-and-place tool equipped with computer vision technology to recognize the orientation/locations of the bonding pads 117, such that the die 200 (and the die connectors 201) may be oriented in the correct direction by the pick-and-place tool for bonding with the bonding pads 117. The different shapes of the dummy bonding pads 117B may also help a human operator to reduce error during testing or trouble shooting, especially when the die 200 has a symmetric shape and the locations of the die connectors 201 may remain the same even if the die 200 is rotated by, e.g., 90 degrees or 180 degree. In addition, by not limiting the sizes and shapes of the dummy bonding pads 117B to match those of the dummy die connectors 201B, the designer of the interposer 100 has more freedom in choosing the sizes and shapes of the dummy bonding pads 117B, thereby making it easier to achieve substantially uniform metal density at the surface of the interposer 100, which in turn helps to reduce or avoid surface unevenness (e.g., dishing).

FIG. 6D illustrates another example cross-sectional view of the semiconductor structure 300 along cross-section A-A in FIG. 6A. FIG. 6D is similar to FIG. 6C, but with some differences. For example, in the top view (or plan view), the circular shape of the dummy die connector 201B is inscribed in the shape (e.g., hexagon, or pentagon) of the dummy bonding pad 117B. In other words, the center of the circle coincides (e.g., overlaps) with the center of the hexagon (or pentagon), and the circle touches each side of the hexagon (or pentagon) at a single point without crossing it.

FIG. 6E illustrates yet another example cross-sectional view of the semiconductor structure 300 along cross-section A-A in FIG. 6A. In FIG. 6E, the dummy bonding pads 117B (e.g., 117B1 and 117B2) have a first shape (e.g., a cross shape), and the bonding pads 117A have a second shape (e.g., a circular shape). The center of each dummy die connector 201B coincides (e.g., overlaps) with the center of the corresponding dummy bonding pad 117B. Notably, although the dummy bonding pads 117B1 and 117B2 have the same shape, there is a rotation between the shapes of the dummy bonding pads 117B1 and 117B2. For example, the two axes L₁ and L₂ of the cross shape of the dummy bonding pad 117B2 are aligned with the vertical direction and the horizontal direction of FIG. 6E, respectively, and therefore, are aligned with the row direction and the column direction of the array of bonding pads 117A. The two axes L₁ and L₂ of the cross shape of the dummy bonding pad 117B1 are rotated with respect to those of the dummy bonding pad 117B2, thus are not aligned with the row direction and the column direction of the array of bonding pads 117A. Therefore, the angle between the axis L₁ (or L₂) of the cross shape of the dummy bonding pads 117B and the row direction (or column direction) of the array of bonding pads 117B may be used to distinguish the dummy bonding pads 117B1 and 117B2, and the locations of the dummy bonding pads 117B1 and 117B2 may be used as reference points for a pick-and-place tool equipped with computer vision technology to properly rotate the die 200 for bonding.

FIG. 7A illustrates a cross-sectional view of a semiconductor structure 300A, in another embodiment. The semiconductor structure 300A is similar to the semiconductor structure 300, but each of the dummy bonding pads 117B of the semiconductor structure 300A includes discrete portions of the conductive material, instead of one single continuous volume of the conductive material. In addition, in the example of FIG. 7A, the die 200 does not have dummy die connectors 201B that are bonded to the dummy bonding pads 117B. Instead, the upper surfaces of the dummy bonding pads 117B are in contact with the dielectric layer 203 of the die 200.

FIG. 7B illustrates the cross-sectional view of the semiconductor structure 300A along cross-section A-A in FIG. 7A. For simplicity, only a portion of the semiconductor structure 300A including the dummy bonding pads 117B1 and 117B2 are illustrated. In the example of FIG. 7B, the dummy bonding pad 117B1 (or 117B2) is similar to the dummy bonding pad 117B1 (or 117B2) in FIG. 6C, but with segments of the conductive material removed and replaced with materials of the bonding film 112, and the remaining segments of the dummy bonding pad 117B1 (or 117B2) forming discrete portions of the dummy bonding pad 117B1 (or 117B2). Note that the exterior boundaries of the discrete portions of the dummy bonding pads 117B1 and 117B2 still have the pentagon shape and the hexagon shape, respectively. The dummy bonding pads 117B (e.g., 117B1 and 117B2) of FIGS. 7A and 7B may be formed by forming pad openings with discrete openings portions in the bonding film 112, and filling the discrete portions of each of the pad openings with the conductive material.

The die 200 in the semiconductor structure 300A does not need to form the dummy die connectors 201B, thus simplifying production and saving cost. In addition, portions of the dielectric layer 113 disposed between the discrete portions of the dummy bonding pad 117B may form direct dielectric-to-dielectric bonding with the dielectric layer 203 of the die 200, thus improving the bonding strength between the die 200 and the interposer 100.

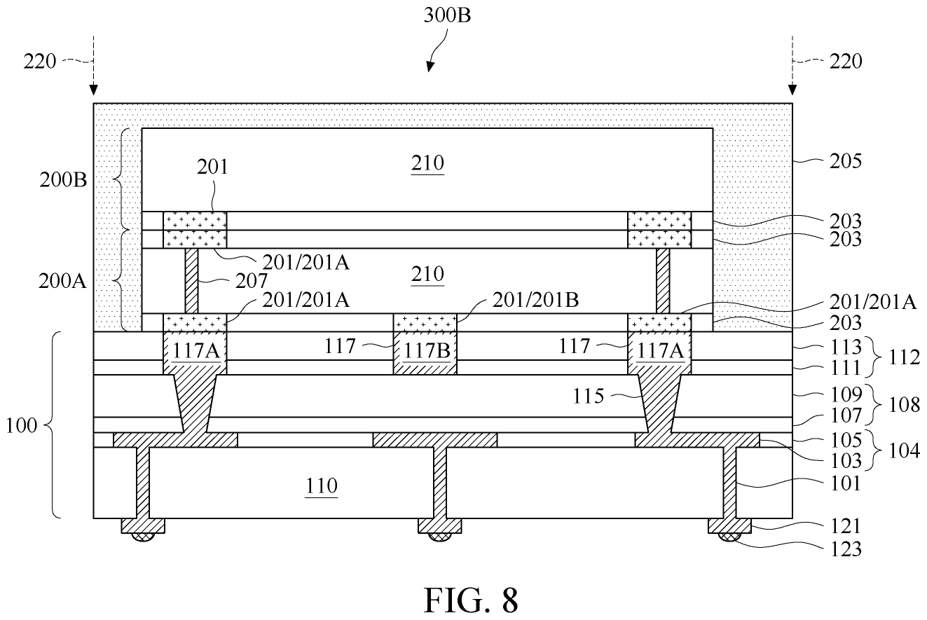

FIG. 8 illustrates a cross-sectional view of a semiconductor structure 300B, in yet another embodiment. The semiconductor structure 300B is similar to the semiconductor structure 300, but with more vertical stacking of dies. For example, a first die 200A is bonded to the interposer 100, and a second die 200B is bonded to an upper surface of the first die 200A.

The first die 200A is similar to the die 200, but with additional die connectors 201 formed at the upper surface of the first die 200A distal from the interposer 100. In addition, through-substrate-vias (TSVs) 207 are formed in the first die 200A to electrically couple the die connectors 201 at the upper surface and the lower surface of the first die 200A. In the illustrated embodiment, dummy die connectors 201B are formed at the lower surface of the first die 200A for bonding with the dummy bonding pads 117B of the interposer 100, and no dummy die connector 201B is formed at the upper surface of the first die 200A.

The second die 200B is similar to the die 200, but with no dummy die connectors 201B formed. The die connectors 201 of the second die 200B are bonded to corresponding die connectors 201 at the upper surface of the first die 200A. The molding material 205 encapsulates both the first die 200A and the second die 200B.

Embodiments may achieve advantages. For example, the disclosed passivation film 108 for the interposer 100 includes only one ESL layer 107 and one dielectric layer 109, which simplifies the film scheme, reduces production cost and process time. In addition, due to the reduced thickness of the passivation film 108, vias 115 formed in the passivation film 108 have shorter lengths and larger bottom surfaces, which reduce the electrical resistance of the vias 115. Furthermore, the disclosed passivation film 108 only has one interface between the ESL and the dielectric layer within the passivation film 108, which in turn reduces the risk of delamination of the passivation film 108 from the vias 115. Since the interposer 100 is used for forming the semiconductor structure 300 (or 300A, 300B), the passivation film 108 is subject to subsequent high-temperature processes, such as the bonding process for the die 200 and the molding process for forming the molding material 205. The high-temperature processes, together with the mismatch of the coefficients of thermal expansion (CTEs) between the molding material 205 and the interposer 100, may cause high stress in the passivation film 108 and may result in delamination of the passivation film 108. Delamination of the passivation film 108 may result in device failure in the semiconductor device 300 (or 300A, 300B). The disclosed structure for passivation film 108, by reducing the risk of delamination, reduces device failure in the semiconductor structure 300 (or 300A, 300B) and increases production yield.

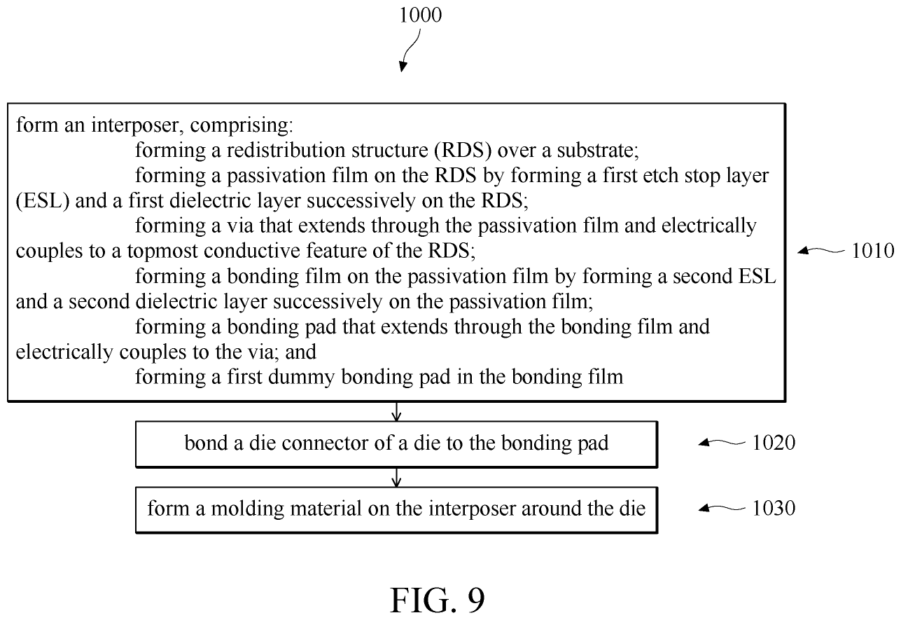

FIG. 9 illustrates a flow chart of a method 1000 of forming a semiconductor structure, in some embodiments. It should be understood that the embodiment method shown in FIG. 9 is merely an example of many possible embodiment methods. One of ordinary skill in the art would recognize many variations, alternatives, and modifications. For example, various steps as illustrated in FIG. 9 may be added, removed, replaced, rearranged and repeated.

Referring to FIG. 9, at block 1010, an interposer is formed, wherein forming the interposer comprises: forming a redistribution structure (RDS) over a substrate; forming a passivation film on the RDS by forming a first etch stop layer (ESL) and a first dielectric layer successively on the RDS; forming a via that extends through the passivation film and electrically couples to a topmost conductive feature of the RDS; forming a bonding film on the passivation film by forming a second ESL and a second dielectric layer successively on the passivation film; forming a bonding pad that extends through the bonding film and electrically couples to the via; and forming a first dummy bonding pad in the bonding film. At block 1020, a die connector of a die is bonded to the bonding pad. At block 1030, a molding material is formed on the interposer around the die.

In accordance with an embodiment, a semiconductor structure includes an interposer, wherein the interposer comprises: a substrate; a redistribution structure (RDS) on a first side of the substrate; a passivation film on the RDS, wherein the passivation film comprises a first etch stop layer (ESL) on the RDS and a first dielectric layer on the first ESL; a via embedded in the passivation film, wherein the via is electrically coupled to a conductive feature of the RDS; a bonding film on the passivation film, wherein the bonding film comprises a second ESL on the passivation film and a second dielectric layer on the second ESL; and a bonding pad and a first dummy bonding pad that are embedded in the bonding film, wherein the bonding pad is electrically coupled to the via, and the first dummy bonding pad is electrically isolated. The semiconductor structure further includes a die attached to the interposer, wherein a die connector of the die is bonded to the bonding pad. In an embodiment, a thickness of the passivation film is equal to a sum of a thickness of the first ESL and a thickness of the first dielectric layer. In an embodiment, a thickness of the bonding film is equal to a sum of a thickness of the second ESL and a thickness of the second dielectric layer. In an embodiment, the first ESL and the second ESL are a same material, wherein the first dielectric layer and the second dielectric layer are a same material. In an embodiment, the first ESL and the second ESL are silicon nitride, silicon carbide, silicon carbonitride, or silicon oxynitride, and wherein the first dielectric layer and the second dielectric layer are silicon oxide. In an embodiment, a first dummy die connector of the die is bonded to the first dummy bonding pad, wherein the first dummy die connector is electrically isolated. In an embodiment, in a top view, the bonding pad and the first dummy bonding pad have different shapes. In an embodiment, the interposer further comprises a second dummy bonding pad embedded in the bonding film, wherein in the top view, each of the bonding pad, the first dummy bonding pad, and the second dummy bonding pad has a different shape. In an embodiment, a second dummy die connector of the die is bonded to the second dummy bonding pad, wherein in the top view, the first dummy die connector, the second dummy die connector, and the die connector have a same shape as the bonding pad. In an embodiment, an upper surface of the via is level with an upper surface of the passivation film distal from the substrate, and a lower surface of the via is level with a lower surface of the passivation film facing the substrate. In an embodiment, an upper surface of the bonding pad is level with an upper surface of the bonding film distal from the substrate, and a lower surface of the bonding pad is level with a lower surface of the bonding film facing the substrate.

In accordance with an embodiment, a semiconductor structure includes an interposer that comprises: a substrate; a redistribution structure (RDS) over a first side of the substrate; a passivation film over the RDS, wherein the passivation film comprises a first etch stop layer (ESL) over the RDS and a first dielectric layer over the first ESL; a via extending through the passivation film and electrically coupled to a topmost conductive feature of the RDS; a bonding film over the passivation film, wherein the bonding film comprises a second ESL over the passivation film and a second dielectric layer over the second ESL; a bonding pad extending through the bonding film and electrically coupled to the via; and a first dummy bonding pad embedded in the bonding film. The semiconductor structure further includes: a first die attached to a first side of the interposer, wherein a first die connector of the first die is bonded to the bonding pad; and a molding material over the first side of the interposer and around the first die. In an embodiment, a sum of a first thickness of the first ESL and a second thickness of the first dielectric layer is the same as a third thickness of the passivation film. In an embodiment, a first dummy die connector of the first die is bonded to the first dummy bonding pad. In an embodiment, in a top view, the bonding pad and the first dummy bonding pad have different shapes, wherein the interposer further comprises a second dummy bonding pad embedded in the bonding film, wherein in the top view, the first dummy bonding pad and the second dummy bonding pad have different shapes, wherein a second dummy die connector of the first die is bonded to the second dummy bonding pad. In an embodiment, the first die connector and the first dummy die connector are at a first side of the first die, wherein the first die further comprises a second die connector at a second opposing side of the first die, and comprises a through-substrate via (TSV) that electrically couples the first die connector with the second die connector, wherein the semiconductor structure further comprises a second die attached to the second opposing side of the first die, wherein a third die connector of the second die is bonded to the second die connector of the first die.

In accordance with an embodiment, a method of forming a semiconductor structure includes forming an interposer, which comprises: forming a redistribution structure (RDS) over a substrate; forming a passivation film on the RDS by forming a first etch stop layer (ESL) and a first dielectric layer successively on the RDS; forming a via that extends through the passivation film and electrically couples to a topmost conductive feature of the RDS; forming a bonding film on the passivation film by forming a second ESL and a second dielectric layer successively on the passivation film; forming a bonding pad that extends through the bonding film and electrically couples to the via; and forming a first dummy bonding pad in the bonding film. The method further includes: bonding a die connector of a die to the bonding pad; and forming a molding material on the interposer around the die. In an embodiment, the method further includes bonding a dummy die connector of the die to the first dummy bonding pad. In an embodiment, the bonding pad and the first dummy bonding pad are formed to have different shapes in a top view. In an embodiment, forming the interposer further comprises forming a second dummy bonding pad in the bonding film, wherein the first dummy bonding pad and the second dummy bonding pad are formed to have different shapes in the top view.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor structure comprising:
an interposer, wherein the interposer comprises:
a substrate;
a redistribution structure (RDS) on a first side of the substrate;
a passivation film on the RDS, wherein the passivation film has a first dual-layered structure that includes a first etch stop layer (ESL) on the RDS and a first dielectric layer on the first ESL;
a via embedded in the passivation film and electrically coupled to a conductive feature of the RDS;
a bonding film on the passivation film, wherein the bonding film has a second dual-layered structure that includes a second ESL on the passivation film and a second dielectric layer on the second ESL; and
a bonding pad and a first dummy bonding pad that are embedded in the bonding film, wherein the bonding pad is electrically coupled to the via, and the first dummy bonding pad is electrically isolated; and
a die attached to the interposer, wherein a die connector of the die is bonded to the bonding pad.

2. The semiconductor structure of claim 1, wherein in a top view, the bonding pad has a first shape, and the first dummy bonding pad has a second shape different from the first shape.

3. The semiconductor structure of claim 2, wherein a dummy die connector of the die is bonded to the first dummy bonding pad, wherein the dummy die connector is electrically isolated and has the first shape in the top view.

4. The semiconductor structure of claim 3, wherein in the top view, the dummy die connector is disposed within a boundary of the first dummy bonding pad, and wherein sidewalls of the dummy die connector are spaced apart from sidewalls of the first dummy bonding pad.

5. The semiconductor structure of claim 3, wherein the first shape is a circle, and the second shape is a polygon, wherein in the top view, the dummy die connector is disposed within a boundary of the first dummy bonding pad, a center of the dummy die connector coincides with a center of the first dummy bonding pad, and the circle of the dummy die connector touches each side of the polygon of the first dummy bonding pad at a single point without crossing the side.

6. The semiconductor structure of claim 2, wherein the interposer further comprises a second dummy bonding pad embedded in the bonding film, wherein the second dummy bonding pad has a third shape different from the first shape and the second shape in the top view.

7. The semiconductor structure of claim 2, wherein the interposer further comprises a second dummy bonding pad embedded in the bonding film, wherein in the top view, the second dummy bonding pad has the second shape, and an orientation of the second shape of the second dummy bonding pad is rotated relative to an orientation of the second shape of the first dummy bonding pad.

8. The semiconductor structure of claim 2, wherein the first dummy bonding pad comprises a plurality of discrete portions of a conductive material, wherein the plurality of discrete portions of the conductive material are spaced apart from one another by portions of the bonding film, and wherein in the top view, an exterior boundary of the plurality of discrete portions of the conductive material has the second shape.

9. The semiconductor structure of claim 8, wherein the die connector is embedded in a dielectric layer of the die, wherein a lower surface of the die connector facing the interposer is level with a lower surface of the dielectric layer of the die, wherein an upper surface of the first dummy bonding pad distal from the substrate is in direct contact with the lower surface of the dielectric layer of the die.

10. The semiconductor structure of claim 2, wherein the first ESL has a first thickness, and the first dielectric layer has a second thickness, wherein the first thickness is in a range between one seventh of the second thickness and the second thickness.

11. The semiconductor structure of claim 10, wherein the first thickness of the first ESL is between about 3000 angstroms and about 5000 angstroms.

12. A semiconductor structure comprising:
an interposer comprising:
a substrate;
a redistribution structure (RDS) over the substrate, wherein the RDS comprises layers of a first dielectric material and conductive features embedded in the layers of the first dielectric material;
a passivation film over the RDS and having a dual-layered structure, wherein the passivation film comprises an etch stop layer (ESL) over the RDS and a dielectric layer over the ESL, wherein the ESL comprises a second dielectric material different from the first dielectric material;
a via embedded in the passivation film and electrically coupled to a conductive feature of the RDS;
a bonding film over the passivation film, wherein the bonding film has a same dual-layered structure as the passivation film;
a bonding pad embedded in the bonding film and electrically coupled to the via; and
a first dummy bonding pad embedded in the bonding film, wherein the first dummy bonding pad is electrically isolated;
a first die attached to the interposer, wherein a first die connector of the first die is bonded to the bonding pad; and
a molding material over the interposer and around the first die.

13. The semiconductor structure of claim 12, wherein in a top view, the bonding pad and the first dummy bonding pad have a first shape and a second shape, respectively, wherein the second shape is different from the first shape.

14. The semiconductor structure of claim 13, wherein the first die connector has the first shape in the top view, wherein a first dummy die connector of the first die is bonded to the first dummy bonding pad, wherein in the top view, sidewalls of the first die connector overlap with sidewalls of the bonding pad, and sidewalls of the first dummy die connector are disposed within, and spaced apart from, sidewalls of the first dummy bonding pad.

15. The semiconductor structure of claim 14, wherein the interposer further comprises a second dummy bonding pad embedded in the bonding film, wherein in the top view, the second dummy bonding pad has a third shape different from the second shape and the first shape, wherein a second dummy die connector of the first die is bonded to the second dummy bonding pad.

16. The semiconductor structure of claim 14, wherein the first die connector and the first dummy die connector are at a first side of the first die, wherein the first die further comprises:
a second die connector at a second opposing side of the first die; and
a through-substrate via (TSV) that electrically couples the first die connector to the second die connector, wherein the semiconductor structure further comprises a second die bonded to the second die connector.

17. A method of forming a semiconductor structure, the method comprising:
forming an interposer, comprising:
forming a redistribution structure (RDS) over a substrate;
forming a passivation film on the RDS, wherein the passivation film has a first dual-layered structure and is formed by forming a first etch stop layer (ESL) and a first dielectric layer successively on the RDS;
forming a via in the passivation film that is electrically coupled to a conductive feature of the RDS;
forming a bonding film on the passivation film, wherein the bonding film has a second dual-layered structure and is formed by forming a second ESL and a second dielectric layer successively on the passivation film;
forming a bonding pad in the bonding film that is electrically coupled to the via; and
forming a first dummy bonding pad in the bonding film, wherein the first dummy bonding pad is electrically isolated;
bonding a die connector of a die and a dummy die connector of the die to the bonding pad and first dummy bonding pad, respectively; and
forming a molding material on the interposer around the die.

18. The method of claim 17, wherein the bonding pad and the first dummy bonding pad are formed to have a first shape and a second shape, respectively, in a top view, wherein the second shape is different from the first shape.

19. The method of claim 18, wherein forming the interposer further comprises forming a second dummy bonding pad in the bonding film, wherein the second dummy bonding pad is formed to have a third shape different from the first shape and the second shape in the top view.

20. The method of claim 17, wherein the first ESL is formed to have a first thickness, and the first dielectric layer is formed to have a second thickness, wherein the first thickness is in a range between one seventh of the second thickness and the second thickness.
